(19) United States
(12) Patent Application Publication
(10) Pub. No.: US 2009/0317977 A1
(43) Pub. Date: Dec. 24, 2009

(54) MANUFACTURING METHOD FOR SEMICONDUCTOR DEVICE

(76) Inventor: Akihiro TAKASE, Oita-ken (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/486,469

(22) Filed: Jun. 17, 2009

(30) Foreign Application Priority Data
Jun. 19, 2008 (JP) 2008-160360

(51) Int. Cl. H01L 21/465

(52) U.S. Cl. 438/703; 257/E21.485

(57) ABSTRACT

A manufacturing method for a semiconductor device includes: forming a first deposition film on a surface of a member in a chamber configured to perform plasma etching of a wafer, by introducing a first seasoning gas into the chamber; forming a second deposition film on the first deposition film to coat the first deposition film by introducing a second seasoning gas into the chamber; loading the wafer into the chamber; and performing plasma etching of the wafer.

### CROSS-REFERENCE TO RELATED APPLICATION

This application is based upon and claims the benefit of priority from the prior Japanese Patent Application No. 2008-160360 filed on Jun. 19, 2008, the entire contents of which are incorporated herein by reference.

### BACKGROUND OF THE INVENTION

The present invention relates to a manufacturing method for semiconductor device in which seasoning is performed, for example, in a plasma etching process.

In a manufacturing process of a semiconductor device using Cu wiring, generally, plasma etching is performed after formation of Cu wiring on a wafer. In such a process, seasoning is performed after cleaning of a chamber by previous use of a dummy wafer in order to ensure stable etching characteristics, as described in Japanese Patent No. 3568749 (e.g., claim 1).

After completion of seasoning, plasma etching is performed. At this time, Cu deriving from Cu wiring of a previously processed wafer is adherent to a member such as a chamber innerwall. The adhering Cu repeats oxidation, reduction and fluoridation behaviors with fluorine based etching gas introduced into a chamber. Hence, the etchant is deactivated and thus etching characteristics vary.

While, with further miniaturization of a semiconductor device, higher processing precision is required even for plasma etching, such variations in etching characteristics causes degradation in product performance, reliability and yield due to dimensional variations. However, since it is difficult to remove Cu particles adhering to an inside of the chamber by use of etching gas or the like, seasoning is essential to ensure as stable a process as possible even under such a state where Cu particles are adherent to the inside of the chamber.

Generally, as a method for suppressing an effect of surface deposits by use of seasoning, for example, Japanese Patent Application Laid-Open No. 11-67746 (e.g., claim 1, paragraphs [00010], [0011]) proposes a technique of introducing a film-forming gas such as silane gas and forming a silicon oxide based seasoning layer in a chamber to coat fluorine absorbed and captured in an inner surface of the chamber.

On the other hand, to suppress plasma damage of a plasma processing chamber, there is used a technique of covering a surface of a member, such as a chamber inner wall or a part, formed of an alumina base material with Y₂O₃ film, as disclosed, for example, in Japanese Patent Application Laid-Open No. 2005-225745 (e.g., claim 1). However, in use of such a Y₂O₃ film, when a silicon oxide based or carbon hydride based seasoning layer as described above is formed, the Y₂O₃ film is reduced by hydrogen contained in the layer and hence a reduction-oxidation reaction of Y₂O₃ is induced, which causes a problem that Y dust is generated.

### SUMMARY

According to an aspect of the present invention, there is provided a manufacturing method for a semiconductor device comprising; forming a first deposition film on a surface of a member in a chamber configured to perform plasma etching of a wafer, by introducing a first seasoning gas into the chamber; forming a second deposition film on the first deposition film to coat the first deposition film by introducing a second seasoning gas into the chamber; loading the wafer into the chamber; and performing plasma etching of the wafer.

### BRIEF DESCRIPTION OF THE DRAWINGS

FIG. 1 is a sectional view of a plasma etching apparatus according to an aspect of the present invention;

FIGS. 2 is a partially enlarged sectional view of a chamber inner wall of a plasma etching apparatus according to an aspect of the present invention.

FIG. 3 is a flow chart illustrating a plasma etching process according to an aspect of the present invention; and

FIGS. 4 and 5 are partially enlarged sectional views of a chamber inner wall of a plasma etching apparatus according to an aspect of the present invention.

### DETAILED DESCRIPTION

Reference will now be made in detail to the present embodiment of the invention, an example of which is illustrated in the accompanying drawings. Wherever possible, the same reference numbers will be used throughout the drawing to refer to the same or like parts.

FIG. 1 is a sectional view of a plasma etching apparatus used in the present embodiment. A chamber 11 in which a wafer w is subjected to plasma etching is provided with an upper electrode 12 and a lower electrode 13 disposed to face the upper electrode 12. The lower electrode 13 is supported by a lower portion of the chamber 11 by means of a column 14. There is also provided a susceptor 15 for placing a wafer w on a top face thereof. High-frequency power supplies 16, 17 are connected to the upper electrode 12 and the lower electrode 13 to apply a high-frequency voltage to the upper electrode 12 and the lower electrode 13, respectively.

At the upper portion of the chamber 11, there is provided a gas inlet 18 for introducing an etching gas or the like of predetermined gas type and flow rate. On the other hand, at the lower portion of the chamber 11, there is provided a gas outlet 19 connected with a vacuum pump or the like for gas exhaust. A displacement regulating valve (not illustrated) is connected to the gas outlet 19, which enables control of the inside of the chamber 11 at a predetermined pressure.

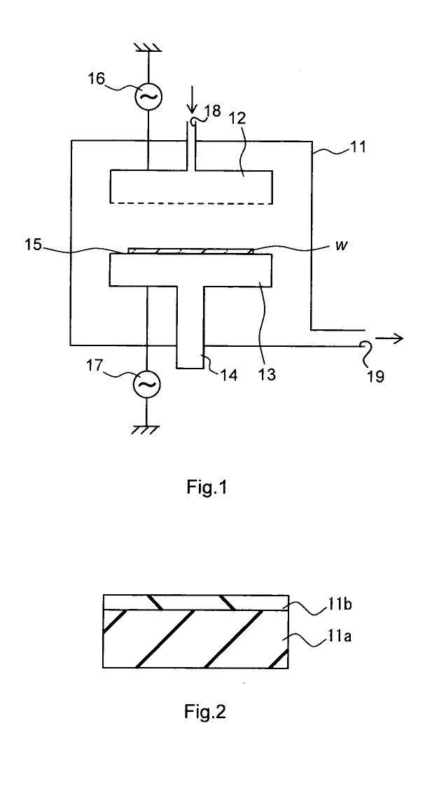

As illustrated in a partially enlarged sectional view of FIG. 2, a member of an inner wall of the chamber 11 is formed of a housing 11a made of alumina and a Y₂O₃ film 11b formed on a surface thereof to suppress plasma damage. In addition to the inner wall, other members, such as the susceptor 15, mounted inside the chamber 11 are also formed of alumina and Y₂O₃ film in the same way.

Using such a plasma etching apparatus, a wafer w is subjected to plasma etching as described below.

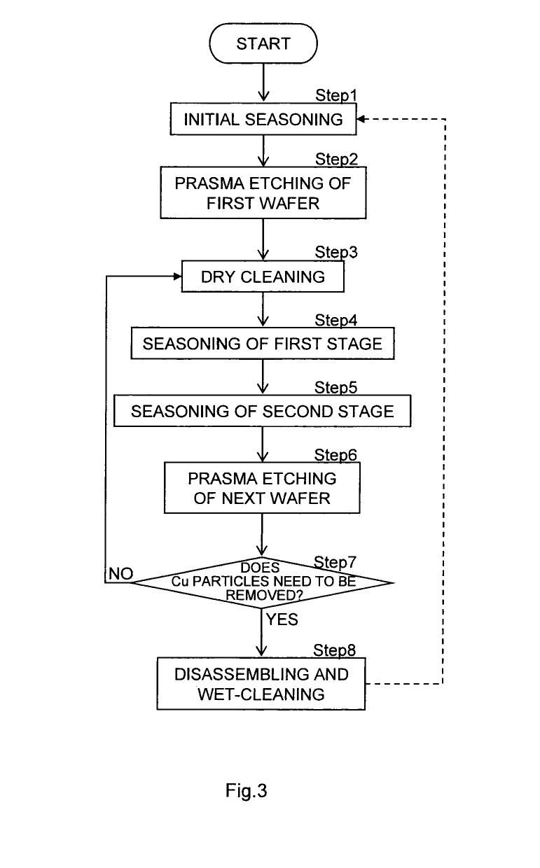

FIG. 3 is a flow chart illustrating a plasma etching process. First, disassembly and wet cleaning are performed and then etching gas is introduced into the chamber 11 having no Cu particles on an inner surface from the gas inlet 18 for initial seasoning (Step 1).

A first wafer w on which lower-layer Cu damascene interconnect is previously formed by a plating method or the like and on which an interlayer insulation film such as SiCOH film and a predetermined resist pattern are formed is loaded into the chamber 11 and placed on the susceptor 15. Then, CF₄, for example, as the etching gas is introduced from the gas inlet 18 and high-frequency voltage is applied to the upper electrode 12 by a high-frequency power supply 16 to generate plasma. The wafer w is subjected to plasma etching, using the generated plasma to form a predetermined pattern (opening) in an interlayer insulation film and the like. Next, the first wafer w is unloaded (Step 2).

Since the lower-layer Cu damascene interconnect is exposed at the opening, Cu particles dropped off the exposed portion are adherent to the member such as the inner wall of the chamber 11.

An etching gas such as O₂ is introduced from the gas inlet 18 for dry cleaning to remove reaction by-product accumulated in the chamber 11 during previous plasma etching (Step 3). The Cu particles adhering to a member of the chamber 11, such as the inner wall thereof, still remain without being removed by the cleaning.

Subsequently, seasoning of a first stage is performed (Step 4). A dummy wafer is loaded into the chamber 11 and placed on the susceptor 15. A gas including CF₄/CH₂F₂, for example, as a seasoning gas is introduced from the gas inlet 18. Further, a high-frequency voltage is applied to the upper electrode 12 by the high-frequency power supply 16 to generate plasma, thereby forming a fluorocarbon based deposition film on a surface of a member such as an inner wall of the chamber 11. In this process, for example, by setting a ratio of CH₂F₂ at a relatively large value such as CH₂F₂ at 20 scm or more with respect to CF₄ at 150 scm, deposition can be positively accelerated.

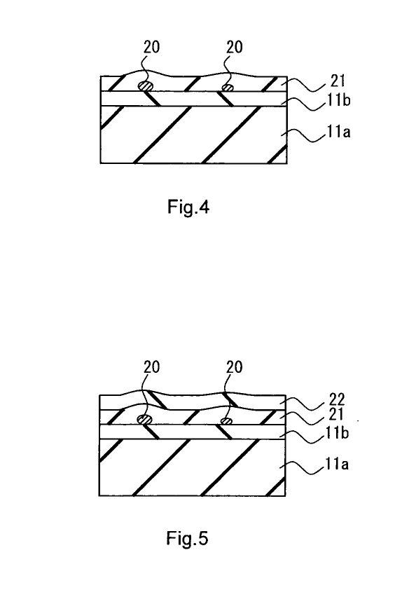

FIG. 4 illustrates a partially enlarged sectional view of an inner wall of the chamber 11 at this point. Cu particles 20 adhering to a surface of the Y₂O₃ film 11b covering the casing 11a made of alumina of the chamber 11 are covered with a deposition film 21.

After forming the deposition film 21, a formation state of the deposition film 21 is checked as needed. For example, it is checked whether the deposition film 21 has a sufficient film thickness of, for example, at least 0.5 μm by OES (Optical Emission System) or the like used in dry cleaning.

Subsequent to the seasoning of the first stage, seasoning of a second stage is performed (Step 5). A gas including CH₄/O₂, for example, as a seasoning gas is introduced from the gas inlet 18 in the same way as the seasoning of the previous stage. Similarly, a high-frequency voltage is applied to the upper electrode 12 by the high-frequency power supply 16 to generate plasma, thereby forming a hydrocarbon based deposition film on a surface of the fluorocarbon based deposition film. In this process, for example, by setting a ratio of C (carbon) at a large value such as O₂ at 70 scm with respect to CH₄: 250 scm, deposition can be positively accelerated.

FIG. 5 is a partially enlarged sectional view of an inner wall of the chamber 11 at this point. Cu particles 20 adhering to a surface of the Y₂O₃ film 11b covering the housing 11a made of alumina of the chamber 11 are coated with a deposition film 22.

After forming the deposition film 22, a film formation state of the deposition film 22, for example, whether the deposition film 22 is formed to have a sufficient film thickness of at least 0.5 μm is checked, as needed, in the same way as seasoning of the previous stage.

After performing two-stage seasoning in this way, the wafer won which lower-layer Cu damascene interconnect is previously formed by a plating method and on which an interlayer insulation film such as SiCOH film and a predetermined resist pattern are formed is carried into the chamber 11 and placed on the susceptor 15, in the same way as after the initial seasoning. Then, CF₄, for example, as an etching gas is introduced from the gas inlet 18 and a high-frequency voltage is applied to the upper electrode 12 by the high-frequency power supply 16 to generate plasma, thereby performing plasma etching on the wafer w. After forming a predetermined pattern (opening) in an interlayer insulation film and the like of the wafer w, the wafer w is unloaded (Step 6).

Subsequently, the next wafer is subjected to plasma etching. In the previous plasma etching, a part of the hydrocarbon based deposition film 22 formed on a surface of the member such as the inner wall of the chamber 11 is removed by the introduced etching gas. Similarly, by performing plasma etching on the wafer, the lower-layer Cu damascene interconnect is exposed at the opening and therefore Cu particles newly dropped off the exposed portion are adherent to the member such as the inner wall of the chamber 11.

Accordingly, dry cleaning (Step 3), seasoning of the first stage (Step 4) and seasoning of the second stage (Step 5) are performed in the chamber 11 again in the same way. Similarly, the next wafer is loaded into the chamber 11 and, after completion of plasma etching, the wafer w is unloaded (Step 6). As described above, a plurality of wafers are subjected to plasma etching while two-stage seasoning is being performed for each processing of a wafer.

Then, it is determined whether Cu particles need to be removed (Step 7). When it is determined that Cu particles adhering to the chamber 11 need to be removed, the chamber 11 is disassembled and wet-cleaned (Step 8).

In the present embodiment, the two-stage seasoning is performed for each plasma etching of one wafer, but the two-stage seasoning may be performed on a plurality of wafers, depending upon a pollution condition of the chamber 11.

In the present embodiment, CF₄/CH₂F₂ which is gas including fluorocarbon gas is used as seasoning gas of the first stage, but the present invention is not limited thereto. The seasoning gas maybe any gas which is inactive against a member in the chamber and capable of forming a deposition film which re-dissociates to work as an etchant.

Since the first deposition film to be formed does not need to be totally inactive against a member in the chamber and it is sufficient if the member in the chamber is not reduced which causes dust to be generated, the first deposition film preferably contains fluorine. Such a deposition film containing fluorine is re-dissociated by high-frequency discharge to generate F radical and work as etchant.

As the gas for generating such a deposition film containing fluorine, a gas including at least one type of fluorocarbon gas may be used. As such a gas including at least one type of fluorocarbon gas, CH₃F/N₂, CF₄/H₂ may be used in addition to CF₄/CH₂F₂.

As the seasoning gas for the second stage, CH₄/O₂ which is a gas including hydrocarbon gas is used, but the seasoning gas for the second stage may be any gas which forms a deposition film active against a member in the chamber. Further, other gases such as a gas including at least one type of hydrocarbon based gas such as C₂H₄ and a gas including at least one type of silane based gas such as SiH₄, SiH₂Cl₂ (dichlorosilane).

In this process, by including O₂ gas at a predetermined flow rate, generation of dust is suppressed, which enables more stable formation of a hydrocarbon based or silicon based deposition film. Such a second deposition film allows a process to be stable without working as etchant during plasma processing of the wafer w although a part thereof re-dissociates.

In any seasoning gas, preferably, the ratio of C (carbon) is high from the viewpoint of the film formation efficiency of a deposition film. Also in view of film formation efficiency of the deposition film, the temperature is preferably low. Where there is a cooling function in the susceptor 15 or the like, it is preferable to cool inside the chamber by driving the cooling function in the same way as for plasma etching.

In the present embodiment, the film thickness of each of the deposition films 21, 22 is checked by OES or the like, but a film formation state can also be checked by exposing the inside of the chamber 11 to the atmosphere once, disassembling the chamber 11 and measuring the film thickness of each of the actual deposition films 21, 22, thereby determining the film formation conditions of the deposition films 21, 22.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A manufacturing method for a semiconductor device, comprising:
forming a first deposition film on a surface of a member in a chamber configured to perform plasma etching of a wafer, by introducing a first seasoning gas into the chamber;
forming a second deposition film on the first deposition film to coat the first deposition film by introducing a second seasoning gas into the chamber;
loading the wafer into the chamber; and
performing plasma etching of the wafer.

2. The manufacturing method for a semiconductor device according to claim 1, wherein the wafer has a Cu wiring layer.

3. The manufacturing method for a semiconductor device according to claim 1, wherein a Y₂O₃ film is formed on the surface of the member in the chamber.

4. The manufacturing method for a semiconductor device according to claim 3, wherein the member in the chamber includes alumina.

5. The manufacturing method for a semiconductor device according to claim 1, wherein the first deposition film re-dissociates under conditions of the plasma etching to work as an etchant.

6. The manufacturing method for a semiconductor device according to claim 1, wherein the first deposition film is formed to be at least 0.5 μm in thickness.

7. The manufacturing method for a semiconductor device according to claim 1, wherein the first deposition film contains fluorine.

8. The manufacturing method for a semiconductor device according to claim 7, wherein the first deposition film re-dissociates under conditions of the plasma etching and generates a F radical.

9. The manufacturing method for a semiconductor device according to claim 1, wherein the first seasoning gas includes at least one type of fluorocarbon based gas.

10. The manufacturing method for a semiconductor device according to claim 9, wherein the fluorocarbon based gas includes any of CF₄/CH₂F₂, CH₃F/N₂ and CF₄/H₂.

11. The manufacturing method for a semiconductor device according to claim 1, wherein an inside of the chamber is cooled in forming the first deposition film.

12. The manufacturing method for a semiconductor device according to claim 1, wherein the second deposition film is active against the member in the chamber.

13. The manufacturing method for a semiconductor device according to claim 1, wherein the second deposition film is at least 0.5 μm in thickness.

14. The manufacturing method for a semiconductor device according to claim 1, wherein the second seasoning gas includes at least one type of hydrocarbon based gas and/or silane based gas.

15. The manufacturing method for a semiconductor device according to claim 14, wherein the hydrocarbon based gas includes either one of CH₄ and C₂H₄.

16. The manufacturing method for a semiconductor device according to claim 14, wherein the silane based gas includes either one of SiH₄ and SiH₂Cl₂.

17. The manufacturing method for a semiconductor device according to claim 1, wherein the second seasoning gas includes O₂ gas.

18. The manufacturing method for a semiconductor device according to claim 1, wherein an inside of the chamber is cooled in forming the second deposition film.

19. The manufacturing method for a semiconductor device according to claim 1, wherein initial seasoning is performed with etching gas before introduction of the first seasoning gas.

20. The manufacturing method for a semiconductor device according to claim 1, wherein the etching gas includes O₂ gas.
